(19) United States
(12) Patent Application Publication
(10) Pub. No.: US 2024/0429058 A1
(43) Pub. Date: Dec. 26, 2024

(54) IN-SITU ETCHING OF GALLIUM OXIDE WITH METAL ORGANIC GALLIUM PRECURSORS

(71) Applicant: Nidhin Kurian Kalarickal, Tempe, AZ (US)

(72) Inventor: Nidhin Kurian Kalarickal, Tempe, AZ (US)

(21) Appl. No.: 18/743,610

(22) Filed: Jun. 14, 2024

Related U.S. Application Data
(60) Provisional application No. 63/509,892, filed on Jun. 23, 2023.

(51) Int. Cl. H01L 21/3065; H01L 21/308

(52) U.S. Cl. CPC H01L 21/3065; H01L 21/3081

(57) ABSTRACT

Damage-free etching of Ga₂O₃ includes loading a Ga₂O₃ sample in a metal organic chemical vapor deposition (MOCVD) reactor, heating the Ga₂O₃ sample, and contacting the Ga₂O₃ sample with a metal organic gallium precursor to yield gallium and hydrocarbon components, thereby etching the Ga₂O₃ sample with the gallium. The Ga₂O₃ includes β-phase (monoclinic) Ga₂O₃, α-phase (corundum) Ga₂O₃, κ-phase (orthorhombic) Ga₂O₃, γ-phase (defective spinel) Ga₂O₃. The metal organic gallium precursor includes triethyl gallium (TEGa), and trimethyl gallium (TMGa).

### CROSS-REFERENCE TO RELATED APPLICATION

This application claims the benefit of U.S. Patent Application No. 63/509,892 filed on Jun. 23, 2023, which is incorporated herein by reference in its entirety.

### STATEMENT OF GOVERNMENT SUPPORT

This invention was made with government support under 1542160 awarded by the National Science Foundation. The government has certain rights in the invention.

### TECHNICAL FIELD

This invention relates to in-situ etching of gallium oxide (Ga₂O₃) with metal organic gallium precursors, such as trimethyl gallium and triethyl gallium.

### BACKGROUND

Ga₂O₃ is an ultra-wide band gap semiconductor having potential utility in power switching and high frequency power amplifying devices. Ga₂O₃ forms in several different polymorphs namely β-phase (monoclinic), α-phase (corundum), κ-phase (orthorhombic), and γ-phase (defective spinel).

Dry etching recipes in Ga₂O₃ have typically been found to cause subsurface damage resulting in charge depletion and degradation of mobility. Wet etching recipes can form angled sidewalls, making the formation of scaled sub-micron fins/trench structures difficult. Metal assisted chemical etching can result in non-stoichiometric etched surfaces, leading to reduced Schottky barrier heights.

### SUMMARY

An in situ etching method for β-Ga₂O₃ using a metal organic gallium precursor as an etching agent is disclosed. At sufficient substrate temperature (T_{sub}), the precursor is introduced into the reactor and undergoes pyrolysis, depositing Ga on the β-Ga₂O₃ surface. The Ga adatoms react with Ga₂O₃ to form volatile gallium suboxide (Ga₂O), which desorbs from the β-Ga₂O₃ surface and etches the epilayer. The etch rate and surface morphology are due at least in part to reactor parameters such as precursor molar flow rate, substrate temperature, and chamber pressure. A range of etch rates from about 0.3 m/hr to about 8.5 m/hr was demonstrated by varying the etch parameters. Smooth surface morphology on (010) and (001) β-Ga₂O₃ substrates is also demonstrated. Methods described herein enable damage free fabrication of 3-D structures such as fins and trenches, which are components in many β-Ga₂O₃ device structures.

In a general aspect, a method for damage-free etching of Ga₂O₃ includes loading a Ga₂O₃ sample in a metal organic chemical vapor deposition (MOCVD) reactor, heating the Ga₂O₃ sample, and contacting the Ga₂O₃ sample with a metal organic gallium precursor to yield gallium and hydrocarbon components, thereby etching the Ga₂O₃ sample with the gallium.

Implementations of the general aspect may include one or more of the following features.

Heating the Ga₂O₃ sample can include heating to at least 600° C. The metal organic gallium precursor can include triethyl gallium (TEGa), trimethyl gallium (TMGa), or a combination thereof. The metal organic gallium precursor is typically provided to the MOCVD reactor at a predetermined flow rate. The metal organic gallium precursor undergoes pyrolysis. The Ga₂O₃ sample can include β-phase (monoclinic) Ga₂O₃, α-phase (corundum) Ga₂O₃, κ-phase (orthorhombic) Ga₂O₃, γ-phase (defective spinel) Ga₂O₃, or any combination thereof.

In some cases, the general aspect further includes providing a carrier gas to the reactor to control a pressure in the reactor. In certain cases, the general aspect further includes controlling the predetermined flow rate with a mass flow controller. Etching the Ga₂O₃ sample can include fabricating three-dimensional structures on Ga₂O₃ comprising fins, trenches, nanopillars with vertical sidewalls, or any combination thereof. Some implementations include increasing the surface concentration of dopants underneath an etched surface of the Ga₂O₃ sample.

The etched Ga₂O₃ sample can include a β-(Al_{X}Ga_{1-X})₂O₃ etch stop layer, where X is a number between 0 and 1. In some cases, the damage-free etching of Ga₂O₃ yields a gate recess in a lateral or vertical Ga₂O₃ transistor. In some cases, the damage-free etching of Ga₂O₃ yields a recess for ohmic contacts in a lateral or vertical Ga₂O₃ transistor.

Advantages of atomic Ga flux etching include decreased damage, formation of vertical sidewalls, and an in situ etch process. The in situ nature allows integration of etch with regrowth of epilayers and dielectrics without breaking vacuum, enabling cleaner interfaces. The quality of metal organic chemical vapor deposition (MOCVD) grown β-Ga₂O₃ epilayers is better relative to MBE grown layers. Therefore, it is advantageous to integrate ‘Ga based etching’ in an MOCVD chamber.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 depicts in-situ etching of Ga₂O₃ using metal organic gallium precursors in a reactor.

FIG. 2 depicts a setup of metal organic chemical vapor deposition (MOCVD) in situ Ga etching.

FIG. 3 shows etch rate of β-Ga₂O₃/sapphire as a function of substrate temperature.

FIG. 4 shows etch rate of β-Ga₂O₃/sapphire as a function of triethyl gallium (TEGa) molar flow rate

FIG. 5 shows etch rate of β-Ga₂O₃/sapphire as a function of chamber pressure.

FIG. 6 is a schematic showing conservation of Ga and Ga₂O adatoms on a substrate surface.

FIG. 7 shows a comparison of model with experimental etch rate data as a function of substrate temperature.

FIG. 8 shows a comparison of model with experimental etch rate data as a function of substrate temperature for T_{sub}=800° C.

FIG. 9 shows a comparison of model with experimental etch rate data as a function of substrate temperature for T_{sub}=1000° C.

FIG. 10 shows RMS roughness measured on 5×5 μm² scan area as a function of substrate temperature on (010) and (001) β-Ga₂O₃.

FIG. 11 shows RMS roughness as a function of TEGa molar flow rate on (010) β-Ga₂O₃.

### DETAILED DESCRIPTION

This disclosure describes in situ etching of Ga₂O₃ with metal organic gallium precursors, such as trimethyl gallium (TMGa) and triethyl gallium (TEGa). Both blanket etching and patterned etching using a dielectric mask are disclosed.

As described herein, metal organic (MO) precursors such as TMGa and TEGa are used for etching a Ga₂O₃ sample inside a metal organic chemical vapor deposition (MOCVD) reactor. The Ga₂O₃ sample can include β-phase (monoclinic) Ga₂O₃, α-phase (corundum) Ga₂O₃, κ-phase (orthorhombic) Ga₂O₃, γ-phase (defective spinel) Ga₂O₃, or any combination thereof. The Ga₂O₃ sample is loaded into the MOCVD reactor, and the sample is heated to temperatures >600° C. A MO precursor is supplied into the reactor at a flow rate controlled by a mass flow controller. A carrier gas, such as Ar or N₂, is supplied to the reactor and used to control the chamber pressure in the reactor. The MO precursor contacts the Ga₂O₃ sample to yield gallium and hydrocarbon components. Due at least in part to the increased temperature of the substrate, the MO precursors undergo pyrolysis, or cracking, depositing Ga onto the substrate surface, while the remaining hydrocarbon (C_{X}H_{Y}) is pumped out of the chamber. The process is shown in Equation (1).

C_{X}H_{Y}Ga (g)→C_{X}H_{Y} (g)+Ga (s) (1)

The hydrocarbon components are removed from the MOCVD reactor along with the carrier gas. The Ga deposited on the Ga₂O₃ surface reacts with the Ga₂O₃ surface, forming volatile gallium suboxide (Ga₂O), which etches the Ga₂O₃ according to Equation (2).

4Ga (s)+Ga₂O₃(s)→3Ga₂O (g) (2)

The Ga₂O that forms desorbs from the surface with a rate determined at least in part by the substrate temperature, and effectively results in etching of Ga₂O₃. The etching of Ga₂O₃ can form a gate recess in a lateral or vertical Ga₂O₃ transistor or a recess for ohmic contacts in a lateral or vertical Ga₂O₃ transistor. Ga₂O₃ polymorphs are expected to undergo the same etching as seen in Equation (2). As such, the disclosed method is applicable to a variety of polymorphs. The methods described herein provide techniques for integrating epitaxial growth of Ga₂O₃ with in situ etching.

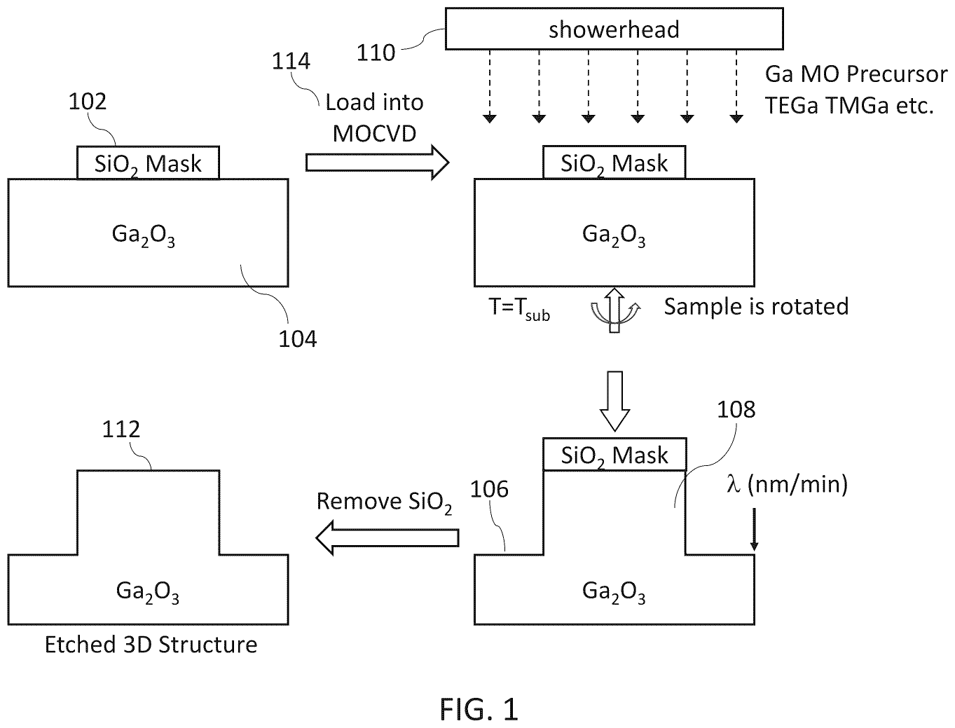

In addition to blanket etching of Ga₂O₃ (no mask on Ga₂O₃), patterned etching of Ga₂O₃ can also be performed as shown in FIG. 1. As depicted in FIG. 1, a dielectric hard mask 102 (e.g., ˜100 nm SiO₂) is deposited using plasma enhanced chemical vapor deposition (PECVD) on a Ga₂O₃ surface 104. The dielectric hard mask 102 is then patterned using lithography and etched using dry or wet etching to create exposed Ga₂O₃ regions 106 and unexposed Ga₂O₃ regions 108 according to the mask pattern. In FIG. 1, an etchant is released from the showerhead 110, covering the SiO₂ dielectric hard mask 102 and the Ga₂O₃ surface 104. The Ga₂O₃ sample can be rotated to expose the Ga₂O₃ surface to the etchant. After the exposed Ga₂O₃ regions 106 and unexposed Ga₂O₃ regions 108 have been created, the SiO₂ dielectric hard mask 102 is removed to yield an etched 3D structure 112.

Etch steps similar to those described with respect to patterned etching can be followed for in situ etching, starting with loading the samples into the MOCVD reactor 114. Metal organic Ga precursors such as TEGa can be used for in situ etching of Ga₂O₃ in an MOCVD chamber, following the reaction shown in Equation (1).

An in situ etching technique for β-Ga₂O₃ inside a MOCVD reactor using TEGa as the etching agent was demonstrated. At sufficiently high substrate temperature (T_{sub}), TEGa was introduced into the MOCVD reactor. The TEGa decomposes through pyrolysis, depositing Ga on the β-Ga₂O₃ substrate surface while the hydrocarbon species is pumped out of the MOCVD chamber. The Ga adatoms reacted with Ga₂O₃ to form Ga₂O as shown in Equation (2). The Ga₂O desorbed from the β-Ga₂O₃ surface, thereby etching the epilayer. The etch rate and surface morphology are due at least in part to MOCVD chamber parameters such as TEGa molar flow rate (f_{TEGa}), substrate temperature (T_{sub}), and chamber pressure (P). A range of etch rates from about 0.3 m/hr to 8.5 m/hr were achieved by varying the etch parameters. Smooth surface morphology on (010) and (001) β-Ga₂O₃ substrates was demonstrated. This etch technique provides damage-free fabrication of 3D structures such as fins, trenches, and nanopillars with vertical sidewalls. These 3D structures are suitable for use in a variety of β-Ga₂O₃ device structures.

The effects of parameters such as TEGa flow rate, substrate temperature (T_{sub}) and substrate orientation ((001) and (010)) on etch characteristics (e.g., etch rate and surface roughness) were determined (e.g., at substrate temperatures ranging from 650° C. to 1000° C.) to determine the effect on etch rate and surface roughness. Pressure was held constant at 1999.84 Pa (15 Torr) throughout the experiments. Samples with a constant etch depth of ˜300 nm were used to measure surface roughness using atomic-force microscopy (AFM). Gallium flux spanned from 3.63 μmol/min to 140.47 μmol/min to determine its effect on the etch rate and surface roughness. The etch rate was found to increase with substrate temperature from 1.8 μm/hr at T_{sub}=700° C. to 3.7 μm/hr at T_{sub}=1000° C. The surface roughness of etched surfaces decreased with increase in T_{sub} for both (010) and (001) Ga₂O₃ surfaces. The etch rate was found to monotonically increase with TEGa flow rates both at T_{sub}=800° C. and T_{sub}=1000° C. At a substrate temperature of 1000° C. and TEGa molar flow rate of 140.5 μmol/min, etch rates exceeding 8.5 μm/hr were achieved. RMS roughness ((010) β-Ga₂O₃ surface) was found to increase at high TEGa flow rates. Lowest surface roughness was obtained at low TEGa flow rates (<12 μmol/min) and T_{sub}=800° C. with the lowest obtained RMS roughness of ˜2.8 nm. Patterned etching using a SiO₂ hard mask was demonstrated with a total etch depth of 2 μm.

The etching experiments were conducted on (2̅01) oriented β-Ga₂O₃ epitaxial films pre-grown on c-plane sapphire substrates using MOCVD and bulk Fe-doped (010) and Sn-doped (001) β-Ga₂O₃ substrates. Experiments were conducted in an Agnitron Agilis 100 MOCVD reactor using TEGa as the source for Ga and nitrogen as the carrier gas. TEGa molar flow rate, substrate temperature (T_{sub}), and chamber pressure (P) in the range of 3.6-140.5 μmol/min, 700-1000° C., and 399.97-7999.34 Pa (3-60 Torr), respectively, were used to determine the effect on etch characteristics.

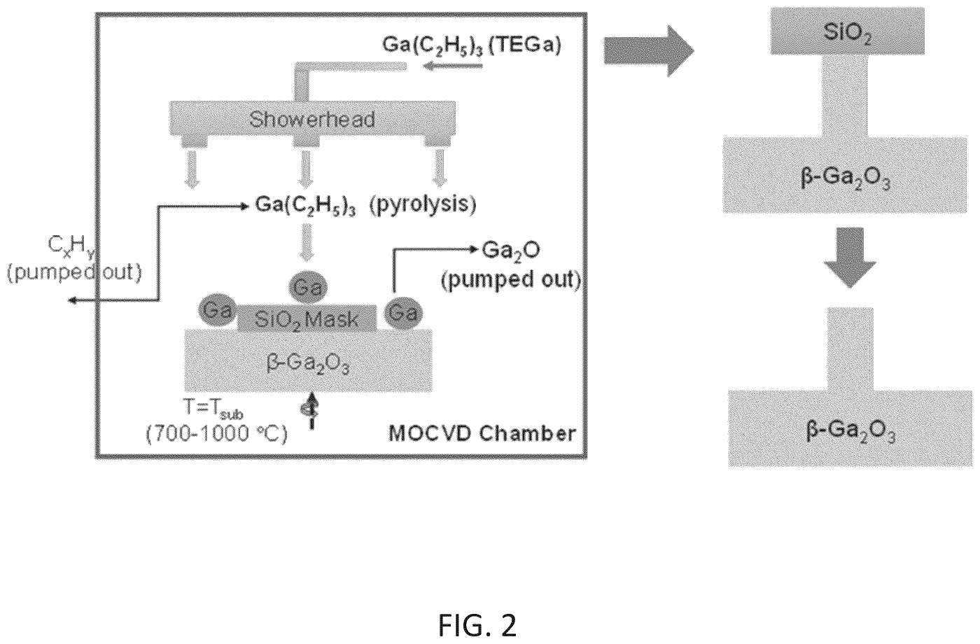

FIG. 2 illustrates the general mechanism of in situ Ga etching of β-Ga₂O₃ in the Agilis 100 MOCVD reactor. TEGa is introduced through the showerhead located above the sample at a distance of 152.4 mm (6 inches) (far injection showerhead). At sufficient substrate temperatures, there is uniform deposition of Ga droplets on the sample surface from pyrolysis of TEGa, demonstrating etching of the β-Ga₂O₃ sample. Blanket etching of the samples is carried out on β-Ga₂O₃/sapphire and β-Ga₂O₃ bulk substrates to estimate the etch rates and surface morphologies. A blue light source (k=470 nm) fiberoptic reflectometer equipped in an Agnitron's Agilis 100 MOCVD reactor is used for in situ monitoring of etch rate. Etch depth and etch rate are estimated by measuring the thickness of samples before and after the etching process (ex situ) using a Filmetirs (F50) thin film analyzer. The presence of refractive index contrast between the β-Ga₂O₃ film and the substrate underneath can contribute to optimizing the optical methods described above. The β-Ga₂O₃/sapphire samples are used to measure the etch rate of the films.

For pattern etched samples, a 200 nm thick SiO₂ layer is used as the hard mask, deposited using plasma enhanced chemical vapor deposition (PECVD) and patterned using optical lithography. Samples are removed from the MOCVD chamber and dipped in HCl to remove Ga droplets (present on the hard mask). The hard mask is later removed using buffered oxide etch (BOE) (1:10).

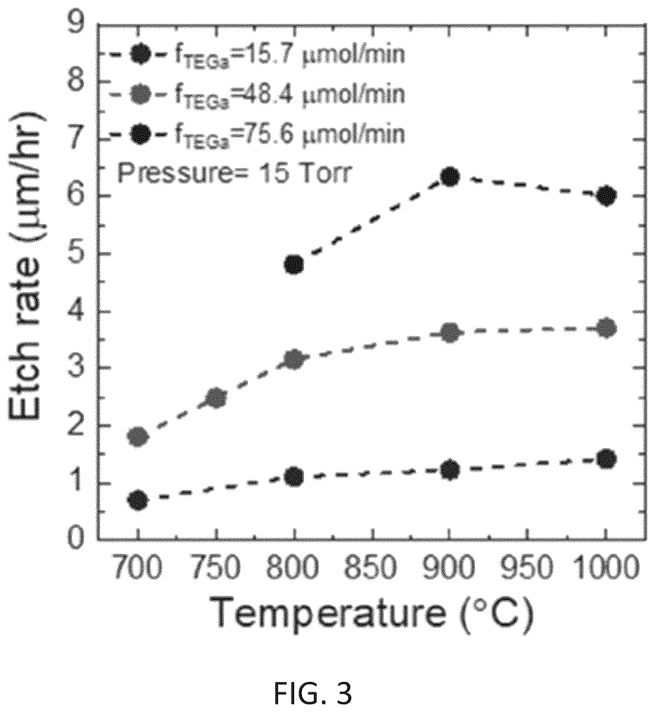

FIG. 3 shows the measured etch rate as a function of substrate temperate (T_{sub}) on β-Ga₂O₃/sapphire. Three different TEGa flow rates of 15.7, 48.4 and 75.6 μmol/min were used with the chamber pressure kept constant at 1999.84 Pa (15 Torr). Etch rate was found to increase with an increase in substrate temperature for the TEGa flow rates. Beyond T_{sub}=900° C., the etch rate was found to saturate with the saturation value of etch rate dependent on the supplied TEGa molar flow rate. At decreased substrate temperatures (T_{sub}<800° C.), etch rate was limited at least in part by the suboxide reaction rate and not by supplied TEGa flow, demonstrating increasing etch rate with substrate temperature. In this etch regime, excess Ga is available on the substrate surface. Pyrolysis of TEGa may not contribute to the temperature dependence of etch rate, since TEGa undergoes pyrolysis above temperatures of approximately 350° C. At high substrate temperature, the Ga supplied is used in the suboxide reaction and the etch rate is limited at least in part by the supplied TEGa flow rate due at least in part to saturation of etch rate.

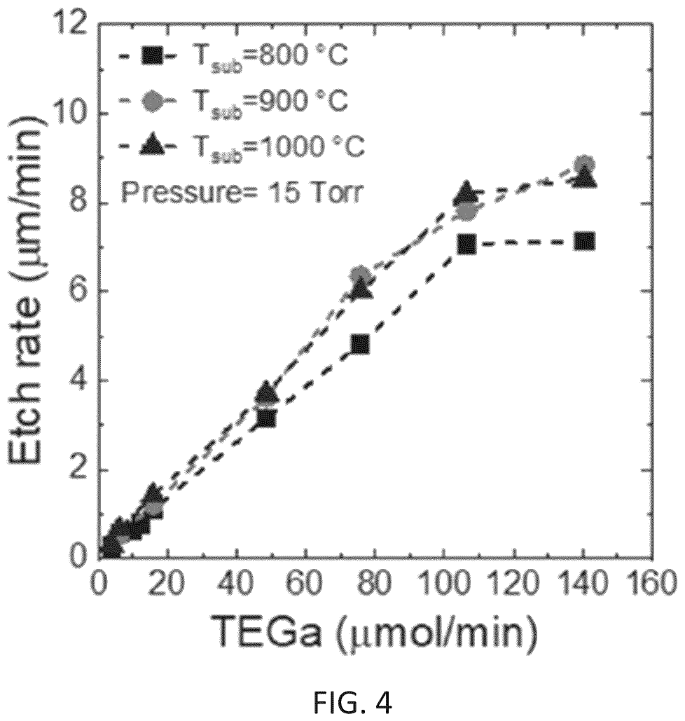

FIG. 4 shows the variation in etch rate as a function of the TEGa molar flow (f_{TEGa}) rate at different substrate temperatures (T_{sub}=800° C., 900° C., 1000° C.). The chamber pressure was kept at a constant value of 1999.84 Pa (15 Torr). At low TEGa flow rates, the etch rate was found to increase linearly with increasing flow rate. As the flow rate was increased, etch rate was found to saturate beyond a critical value of f_{TEGa}. In the linear etch regime, the suboxide reaction rate was sufficient to consume the supplied Ga flux reaching the substrate surface. The linear relationship is due at least in part to the etch rate potentially being limited at least in part by the supplied Ga flux. In the saturation etch regime, saturation of the etch rate may be due at least in part to the supplied Ga flux reaching the sample surface exceeding what can typically be consumed by the suboxide reaction.

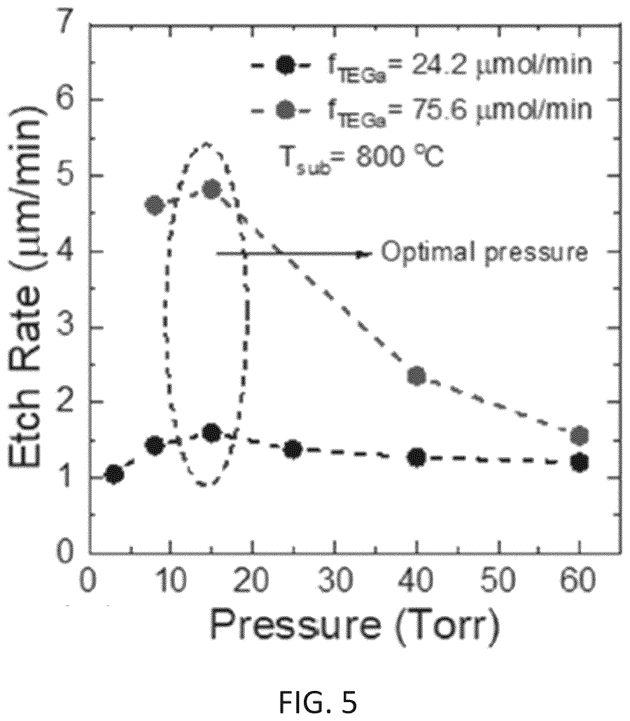

FIG. 5 shows the dependence of etch rate on MOCVD chamber pressure for films etched at a constant substrate temperature of 800° C. using f_{TEGa} of 24.2 and 75.6 μmol/min. For f_{TEGa} values of 24.2 and 75.6 μmol/min, a maximum etch rate was obtained at a chamber pressure of 1999.84 Pa (15 Torr). Etching experiments conducted at pressures below or above 1999.84 Pa (15 Torr) led to a decrease in etch rate, as seen in FIG. 5. The dependence of the residence time of the TEGa vapor on the MOCVD chamber pressure may be a factor. The residence time of a metal organic vapor (e.g., TEGa vapor) in the chamber is directly proportional to the chamber pressure. The chamber pressure may control the speed at which the exhaust system (pump) removes the vapor from the reactor; the exhaust speed is inversely proportional to the reactor pressure. At low reactor pressure, the residence time of TEGa vapor is decreased and the exhaust speed is increased. A decreased etch rate may be due at least in part to a decreased concentration of Ga reaching the substrate surface. The decreased concentration of Ga reaching the substrate surface may be due at least in part to a decreased reactor pressure, a decrease in residence time of TEGa vapor, and an increase in exhaust speed. At high chamber pressure, when residence time for the TEGa vapor is increased and the exhaust speed is decreased, the etch rate may decrease due at least in part to the increased time it takes for the TEGa vapor to reach the substrate surface, potentially demonstrating depletion of the TEGa source on the reactor walls.

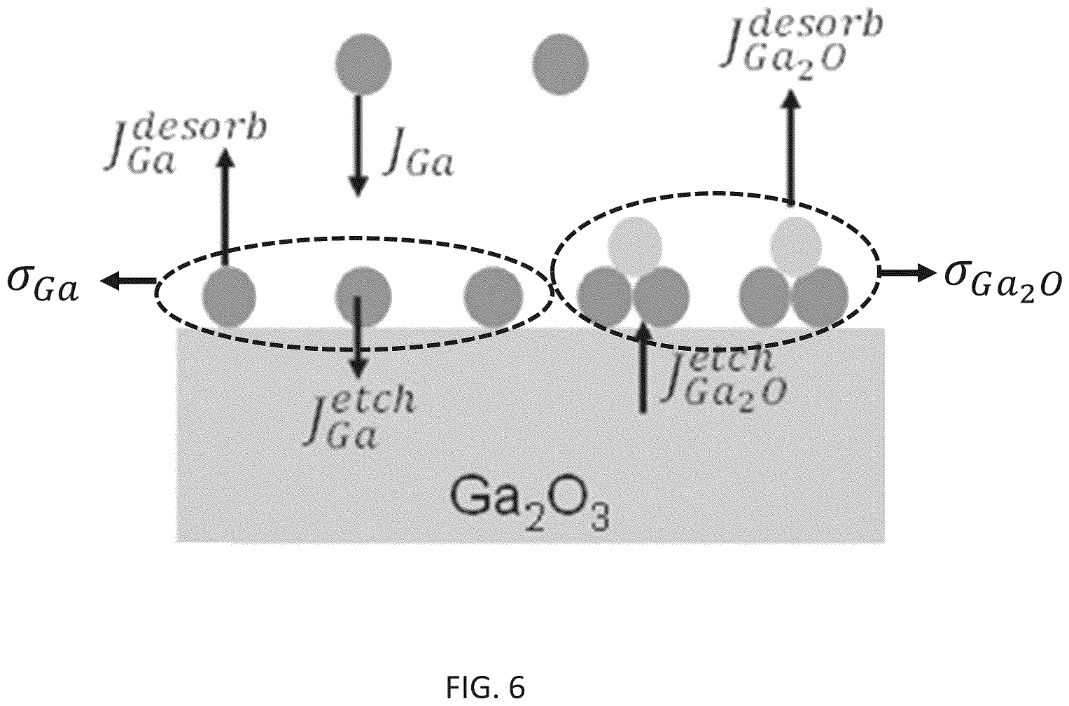

A model for Ga etching is shown below considering conservation of Ga and Ga₂O on the sample surface at a desired pressure condition. In the model, TEGa molecules supplied into the MOCVD chamber are assumed to pyrolyze into Ga and a hydrocarbon group (pumped out) at the desired pressure condition. Pyrolysis of one TEGa molecule produces one Ga atom. The supplied flux of TEGa can be considered as the flux of Ga reaching the substrate surface. FIG. 6 shows the coverage of Ga (σ_{G}a) and Ga₂O (σ_{Ga}_{₂}_{O}) on the sample surface. Coverage in FIG. 6 is defined as the number of adatoms (in the first monolayer) on the sample surface per square centimeter. At decreased Ga flux (TEGa flow), the surface coverage follows Equation (3),

$$\frac{{σ}_{Ga} + {σ}_{{Ga}_{2} O}}{{σ}_{o}} < 1 , \qquad ( 3 )$$

where σₒ is the maximum monolayer surface coverage. Here, an etch model for low Ga flux regime, where Equation (2) is valid, is shown. Below, a high Ga flux regime will be discussed. As shown in FIG. 6, the coverage of Ga adatoms on the sample surface can be determined by the balance between incoming Ga flux (J_{Ga}), rate of Ga consumed in etching (J_{Ga}^{etch}), and desorbed Ga flux (J_{Ga}^{desorb}) The coverage of Ga₂O can be determined by the rate of suboxide formation (J_{Ga}_{₂}_{O}^{etch}), and rate of Ga₂O desorption (J_{Ga}_{₂}_{O}^{desorb}). From particle conservation, Equations (4) and (5) are used.

$$\frac{d {σ}_{Ga}}{dt} = {J}_{Ga} - {J}_{Ga}^{etch} - {J}_{Ga}^{desorb} \qquad ( 4 )$$

$$\frac{d {σ}_{{Ga}_{2} O}}{dt} = {J}_{{Ga}_{2} O}^{etch} - {J}_{{Ga}_{2} O}^{desorb} \qquad ( 5 )$$

The terms J_{Ga}^{etch} and J_{Ga}_{₂}_{O}^{etch} can be written in terms of coverage of Ga (σ_{Ga}) and the suboxide reaction rate

$$( {ke}^{- \frac{{E}_{s}}{{KT}_{sub}}} )$$

as,

$${J}_{Ga}^{etch} = 4 {σ}_{Ga} {ke}^{- \frac{{E}_{s}}{{KT}_{sub}}} \qquad ( 6 )$$

$$and$$

$${J}_{{Ga}_{2} O}^{etch} = 3 {σ}_{Ga} {ke}^{- \frac{{E}_{s}}{{KT}_{sub}}} \qquad ( 7 )$$

where E_{S} is the reaction activation energy, K is the Boltzmann constant, and k is a constant independent of temperature. The numbers 4 and 3 in Equations (6) and (7), respectively, are obtained from the etch stoichiometry (see Equations (1) and (2)). Once J_{Ga}^{etch} and J_{Ga}_{₂}_{O}^{etch} are known, the etch rate of Ga₂O₃(F) can be written as,

$$Γ = \frac{{J}_{Ga}^{etch}}{4 ρ} = \frac{{J}_{{Ga}_{2} O}^{etch}}{3 ρ} \qquad ( 8 )$$

The desorbed flux of Ga (J_{Ga}^{desorb}) and Ga₂O (J_{Ga}_{₂}_{O}^{desorb}) from the sample surface can be written as the product of surface coverage (a) and the desorption rate

$$( {Ae}^{- \frac{{E}_{d}}{{KT}_{sub}}} )$$

giving,

$${J}_{Ga}^{desorb} = {σ}_{Ga} {A}_{1} {e}^{- \frac{{E}_{d 1}}{{KT}_{sub}}} \qquad ( 9 )$$

$$and$$

$${J}_{{Ga}_{2} O}^{desorb} = {σ}_{{Ga}_{2} O} {A}_{2} {e}^{- \frac{{E}_{d 2}}{{KT}_{sub}}} \qquad ( 10 )$$

where A₁, A₂ are constants and E_{d1}, E_{d2} are the energy barriers for desorption. Substituting Equations (6) and (9) into Equation (4), and assuming a steady state (a zero rate of change of surface coverage), the etch rate F can be solved as,

$$Γ = \frac{{J}_{Ga} / 4 ρ}{( 1 + \frac{{A}_{1}}{4 k} {e}^{\frac{{E}_{s} - {E}_{d 1}}{{KT}_{sub}}} )} \qquad ( 11 )$$

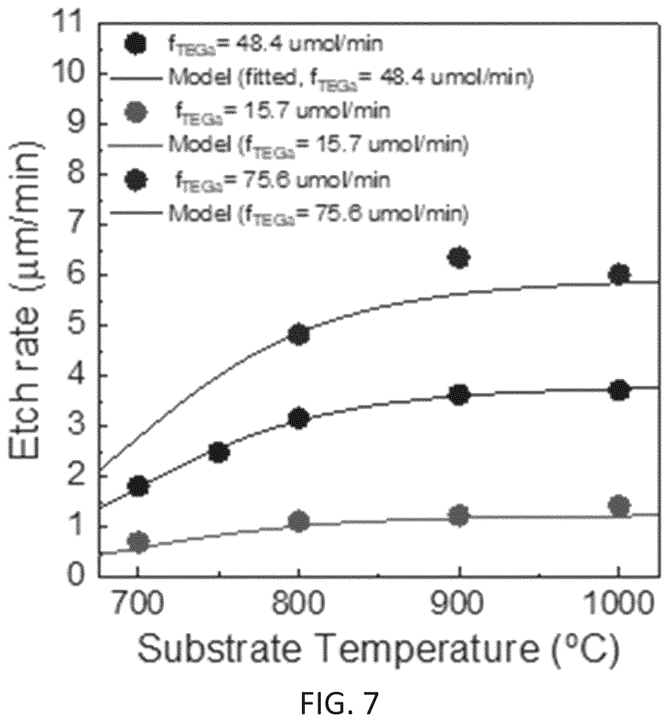

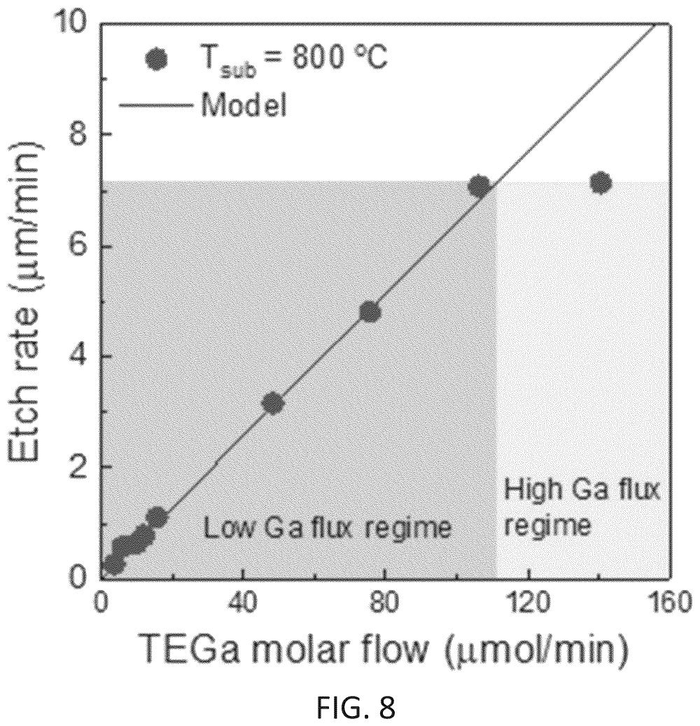

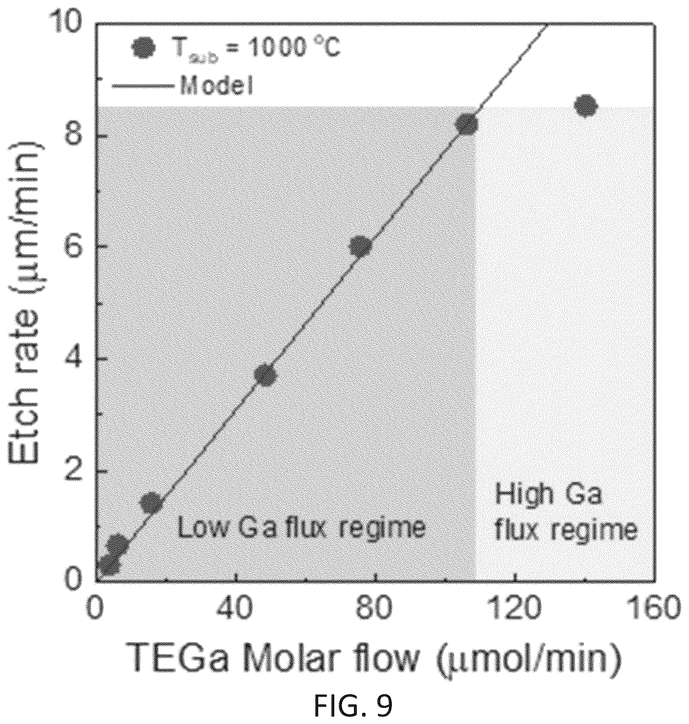

The equation for etch rate can now be written by assuming that the Ga flux (J_{Ga}) is proportional to the molar flow of TEGa (J_{Ga}=Bf_{TEGa}) giving,

$$Γ = \frac{{C}_{1} {f}_{TEGa}}{( 1 + {C}_{2} {e}^{\frac{{E}_{A}}{{KT}_{sub}}} )} \qquad ( 12 )$$

where C₁ (B/4ρ) and C₂ (A₁/4k) are constants and E_{A} is the difference Eₛ−E_{d1}. The constants are estimated by fitting Equation (12) to the experimental data (etch rate versus temperature at f_{TEGa}=48.4 μmol/min) (FIG. 3) and are provided in Table 1. FIGS. 7-9 show a comparison between the model and experimental data and demonstrate a correlation in the low Ga flux regime. The left side of FIGS. 8-9 shows the low Ga flux regime, and the right side shows the high Ga flux regime.

TABLE 1
Fitted values of constants in the etch models

| Parameter | Fitted Value |
|---|---|
| C₁ | 0.079 μm/μmol |
| C₂ | 3.15 × 10⁻⁸ |
| E_{A} | 1.45 eV |

At increased TEGa flow rate, Equation (2) no longer remains valid, and the sample surface saturates with Ga adatoms. The surface saturation of Ga adatoms increases the Ga surface density beyond that of monolayer coverage. The etch rate is then limited by the first monolayer of Ga adatoms due at least in part to only the first monolayer of Ga adatoms being in direct contact with the Ga₂O₃ surface. The monolayer surface coverage of Ga and Ga₂O satisfies Equations (13) and (14).

$$\frac{{σ}_{Ga} + {σ}_{{Ga}_{2} O}}{{σ}_{o}} = 1 , \qquad ( 13 )$$

$$or$$

$${σ}_{Ga} = ( {σ}_{o} - {σ}_{{Ga}_{2} O} ) \qquad ( 14 )$$

The etch rate in the high TEGa flow rate regime is determined by the Ga₂O₃ surface that is uncovered by the suboxide (σ₀−σ_{Ga}_{₂}_{O}). Saturation of the etch rate is due at least in part to the Ga₂O₃ surface that is uncovered by the suboxide (σ₀−σ_{Ga}_{₂}_{O}). The coverage of Ga₂O decreases at high substrate temperature due at least in part to increased desorption. The saturated value of etch rate also increases with substrate temperature as seen in FIG. 4.

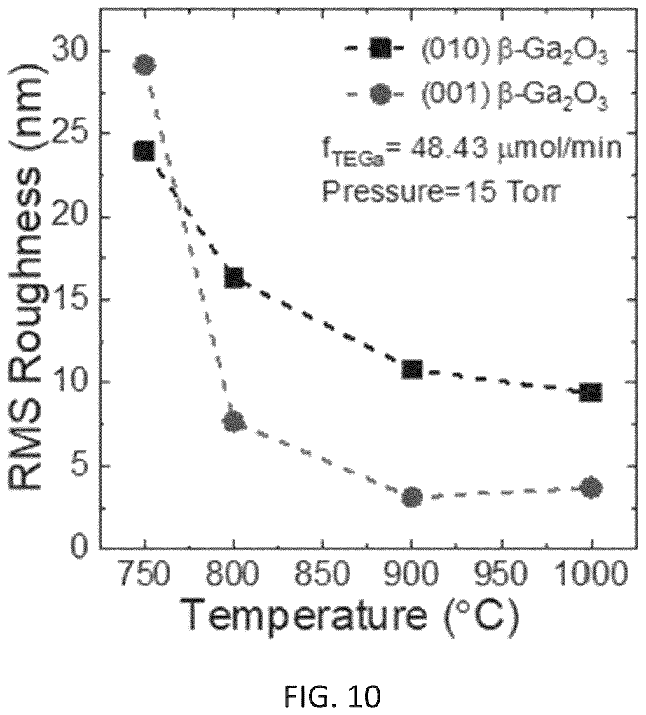

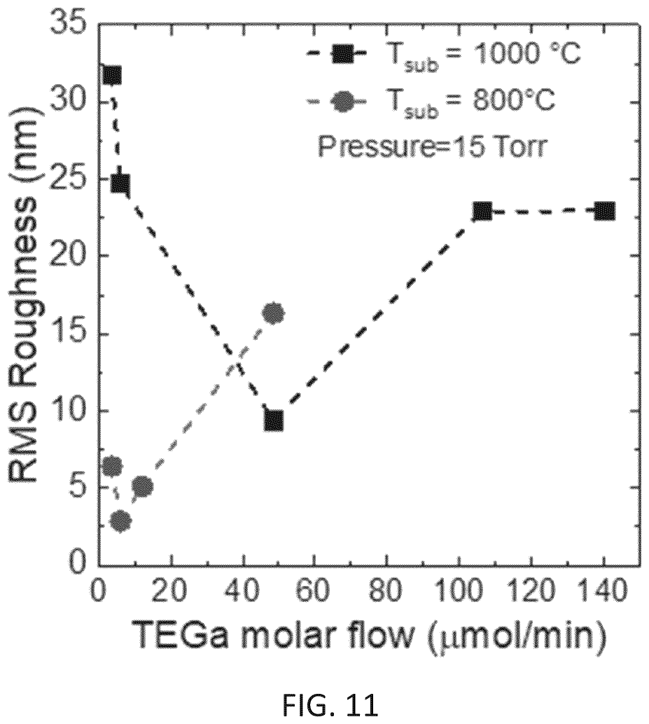

The surface morphology of the etched surface was characterized using atomic force microscopy (AFM). Etch depth for all the samples used in AFM was kept approximately around 300 nm. Fe doped (010) β-Ga₂O₃ substrates and Sn doped (001) β-Ga₂O₃ substrates were used to measure RMS roughness. FIG. 10 shows the variation in RMS roughness of the etched surface as a function of substrate temperature for (001) and (010) β-Ga₂O₃. TEGa molar flow rate (f_{TEGa}=48.4 μmol/min) and chamber pressure 1999.84 Pa (15 Torr) were kept constant in this series of experiments. The RMS roughness of the etched β-Ga₂O₃ surface was found to decrease with increasing substrate temperature for both substrate orientations. The inverse relationship between the RMS roughness of the etched β-Ga₂O₃ surface and the substrate temperature is likely due at least in part to increased surface diffusion of Ga adatoms at higher temperature, demonstrating an increase in uniform surface morphology. The surface morphology of [001] and [010] orientations resembles that of epitaxially grown β-Ga₂O₃ with elongated grooves formed along the [001] for (010) β-Ga₂O₃ and [010] for (001) β-Ga₂O₃ in-plane directions. At low substrate temperature (T_{sub}<700° C.), etch pits were generated due at least in part to preferential etching around defects, which may create an increase in the average surface roughness. In situ Ga etching at decreased substrate temperature may be used to characterize defects in the epilayer by forming etch pits. FIG. 11 shows the variation in RMS roughness of the etched (010) β-Ga₂O₃ surface as a function of TEGa molar flow at T_{sub}=800° C. and 1000° C. A decreased surface roughness of 2.9 nm was obtained at a Ga flux of 6.05 μmol/min and substrate temperature of 800° C. At substrate temperatures of 800° C. and 1000° C., a region of decreased surface roughness was due at least in part to TEGa flow rate. The region of decreased surface roughness shifts to increased TEGa flow rates at increased substrate temperature, as shown in FIG. 11.

AFM scans of both (010) and (001) β-Ga₂O₃ surfaces post Ga etching with decreased RMS roughness (2.8 nm and 3.1 nm) were performed. Blanket etching and patterned etching using SiO₂ hard mask were carried out at T_{sub}=800° C. The hard mask was found to be stable at T_{sub}=800° C. substrate temperature with zero etch rate for the hard mask. Using scanning electron microscopy (SEM) images of pattern etched (010) and (001) β-Ga₂O₃ surface samples using SiO₂ hard mask, it was determined that the SiO₂ mask was removed using buffered oxide etch (BOE) post etching.

In some examples, in situ etching of Ga₂O₃ with metal organic gallium precursors, such as trimethyl gallium (TMGa) and triethyl gallium (TEGa), is used for etching of Ga₂O₃ inside a metal organic chemical vapor deposition (MOCVD) reactor, resulting in an increase in surface concentration of dopants underneath an etched surface of the Ga₂O₃ sample. The substrate may include one or more β-(Al_{X}Ga_{1-X})₂O₃ layers (e.g., as an etch stop layer on the Ga₂O₃ sample), where X is a number between 0 and 1. This in situ damage-free etching of Ga₂O₃ may be used to prepare one or more gate recesses, recess for ohmic contacts, or etching of fins and trenches in a lateral or vertical Ga₂O₃ transistor.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method for damage-free etching of Ga₂O₃, the method comprising:
loading a Ga₂O₃ sample in a metal organic chemical vapor deposition (MOCVD) reactor;
heating the Ga₂O₃ sample;
contacting the Ga₂O₃ sample with a metal organic gallium precursor to yield gallium and hydrocarbon components, thereby etching the Ga₂O₃ sample with the gallium.

2. The method of claim 1, wherein heating the Ga₂O₃ sample comprises heating to at least 600° C.

3. The method of claim 1, wherein the metal organic gallium precursor comprises triethyl gallium (TEGa), trimethyl gallium (TMGa), or a combination thereof.

4. The method of claim 1, further comprising providing a carrier gas to the reactor to control a pressure in the reactor.

5. The method of claim 1, wherein the metal organic gallium precursor undergoes pyrolysis.

6. The method of claim 1, wherein the metal organic gallium precursor is provided to the MOCVD reactor at a predetermined flow rate.

7. The method of claim 6, further comprising controlling the predetermined flow rate with a mass flow controller.

8. The method of claim 1, wherein the Ga₂O₃ sample comprises β-phase (monoclinic) Ga₂O₃, α-phase (corundum) Ga₂O₃, κ-phase (orthorhombic) Ga₂O₃, γ-phase (defective spinel) Ga₂O₃, or any combination thereof.

9. The method of claim 1, wherein etching the Ga₂O₃ sample comprises fabricating three-dimensional structures on Ga₂O₃ comprising fins, trenches, nanopillars with vertical sidewalls, or any combination thereof.

10. The method of claim 1, further comprising increasing the surface concentration of dopants underneath an etched surface of the Ga₂O₃ sample.

11. The method of claim 1, wherein β-(Al_{X}Ga_{1-X})₂O₃ comprises an etch stop layer on the Ga₂O₃ sample, wherein X is a number between 0 and 1.

12. The method of claim 1, wherein the damage-free etching of Ga₂O₃ yields a gate recess in a lateral or vertical Ga₂O₃ transistor.

13. The method of claim 1, wherein the damage-free etching of Ga₂O₃ yields a recess for ohmic contacts in a lateral or vertical Ga₂O₃ transistor.
